(19) United States
(12) Patent Application Publication
(10) Pub. No.: US 2006/0079015 A1
(43) Pub. Date: Apr. 13, 2006

(54) Manufacturing method of pickup device

(75) Inventor: Shigehiro Yamada, Higashihiroshima-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 11/166,346

(22) Filed: Jun. 27, 2005

(30) Foreign Application Priority Data
Jun. 30, 2004 (JP) P2004-192957

(51) Int. Cl. H01L 21/00

(52) U.S. Cl. 438/26; 438/29

(57) ABSTRACT

In a manufacturing method of a pickup device, a hologram element is positioned on a package by turning the hologram element around the Z axis and then by moving the element in the Y-axis direction so as to maximize the light reception intensity of reflected light from the hologram element at a photodetector. This makes it possible to reduce the displacement of the turning angle around the Z axis of the hologram element with respect to the package. Thus, the pickup device is prevented from protruding from the housing when the device is attached to the housing the arrangement of the optical components satisfactorily improved in accuracy, which allows the pickup device to be reduced in size.

### CROSS-REFERENCE TO RELATED APPLICATIONS

This nonprovisional application claims priority under 35 U.S.C. §119(a) on Patent Application No. 2004-192957 filed in Japan on 30 Jun. 2004, the entire contents of which are incorporated herein by reference.

### BACKGROUND OF THE INVENTION

The present invention relates to a method for manufacturing a pickup device for reading data recorded in optical disks (disk-shaped recording media) of, for example, CD (Compact Disc) and DVD (Digital Versatile Disc) and writing data into the optical disks.

According to a conventional manufacturing method of a pickup device, as shown in FIG. 4, when a hologram element 101 is attached to a package 107 to which a light-emitting element 104 and a photodetector 105 are attached, the hologram element 101 has been turned (by an angular displacementθ) around an optical axis (Z axis) of the light-emitting element 104 together with a diffraction grating 102. The above-stated turn is for maximizing the light reception intensity at the photodetector 105 when the light is made incident on the photodetector 105 after the light applied from the light-emitting element 104 is reflected on a disk and diffracted by the hologram element 101 (refer to JP H08-111026 A).

Specifically, as shown in FIG. 5, the hologram element 101 is divided into three regions. Three photodetectors 105, 105a and 105b are provided so as to correspond to the three regions. One photodetector 105 among them has a bisected light-receiving regions A and B on which light 112 diffracted in the first region of the hologram element 101 is made incident. The hologram element 101 is attached to an upper portion of the package 107, and tuned by moving parallel the hologram element 101 in X and Y directions and by turning the hologram element 101 around the Z axis so that outputs of the three photodetectors 105, 105a and 105b achieve prescribed values. In the hologram element 101, the quantity of light in the first region shares a half of the whole, and the quantity of light in the second and third regions shares a quarter of the whole. Therefore, the hologram element 101 is tuned so that the corresponding three photodetectors 105, 105a and 105b produce outputs proportional to these shares (rough tuning process).

Subsequently, tuning has been performed so as to remove the offset of focus error signal (fine tuning process). This has been conducted by turning the hologram element 101 up to an angle of θ₀ around the Z axis from the imaginary line to the solid line, as indicated in the figure, so as to make the diffracted light 112 via the hologram element 101 evenly incident on the two light-receiving regions A and B (i.e., to equalize two outputs from the light-receiving regions A and B).

However, according to the conventional manufacturing method of a pickup device, the hologram element 101 has been tuned only by the turn around the Z axis in the fine tuning process. Therefore, the hologram element 101 has been positioned on the package 107 in a state that the angular displacement (turning angle) around the Z axis of the hologram element 101 has been large with respect to the package 107.

Therefore, a plurality of beams, which have been applied to the disk from the light-emitting element 104 through the diffraction grating 102 and the hologram element 101, have also been positioned with a large angular displacement (angle θ₀) around the Z axis with respect to the package 107.

In this case, when the thus manufactured pickup device is attached to a housing assembled with various optical components, as shown in FIG. 6, it is necessary to attach the pickup device in such a way that the plurality of (three of zeroth-order diffracted light and positive and negative first-order diffracted light generated in the diffraction grating 102) beams 8 emitted from the pickup device are arranged at a definite angle (α) with respect to a track T (line of pits) on the information recording surface of a disk D. It is general to arrange the beams so that the front and rear beams are displaced by about a quarter or a half of the track interval with respect to the center beam.

Therefore, as shown in FIG. 7, if the plurality of beams 8 are positioned with a large angular displacement (angle θ₀) around the Z axis with respect to the package 107 at the time of attaching the pickup device to the housing 109, it has been necessary to perform correction by largely rotational shifting of the package 107 (at an angle (θ₀+α)) with respect to the housing 109 in order to tune the arrangement of the three beams 8 with respect to the track T.

Thus, largely rotational shifting of the package 107 with respect to the housing 109 has had a disadvantage that the package 107 has protruded from the thickness of the housing 109 (with a protrusion amounts). Particularly, a thin type optical pickup device as shown in FIG. 8 is not allowed to tolerate even a slight increase in thickness. In the optical pickup device of FIG. 8, light emitted from the package 107, which is the light source, is reflected upward on a raising mirror 110 and focused on the information recording surface of the disk D by an object lens 111. Therefore, the thickness in the vertical direction of the package 107 becomes a factor to determine the thickness of the optical pickup device.

### SUMMARY OF THE INVENTION

An object of the present invention is to provide a manufacturing method of a pickup device capable of preventing a package from protruding from a housing when the pickup device is attached to the housing by suppressing displacement of a turning angle with respect to the package of a hologram element.

To achieve the above-mentioned object, the present invention provides a manufacturing method of a pickup device, comprising the steps of:

attaching a light-emitting element and a photodetector to a package;

placing a hologram element on the package;

reflecting light applied from the light-emitting element to a disk via the hologram element and making the reflected light incident on the photodetector via the hologram element;

turning the hologram element around an optical axis of the light-emitting element and moving the hologram element in one direction on a plane perpendicular to the optical axis of the light-emitting element so that a light reception intensity of the reflected light at the photodetector is maximized; and

positioning the hologram element on the package.

According to the manufacturing method of a pickup device of the present invention, the hologram element is turned around the optical axis of the light-emitting element and moved in one direction on the plane perpendicular to the optical axis of the light-emitting element so that the light reception intensity of the reflected light at the photodetector can be maximized. This makes it possible to reduce the displacement of the turning angle of the hologram element around the optical axis of the light-emitting element with respect to the package.

Therefore, it is not necessary to perform correction of the package by largely rotational shifting of the pickup device with respect to the housing when the package on which the hologram element is positioned is attached to the housing assembled with various optical components. Thus, the package can be almost prevented from protruding from the housing. As a result, the arrangement of the optical components satisfactorily improved in accuracy, allowing the pickup device to be reduced in size.

In one embodiment of the present invention, the photodetector has two light-receiving regions on which the reflected light is incident, and the light reception intensity at the photodetector is maximized by making the reflected light evenly incident on the two light-receiving regions.

According to the manufacturing method of a pickup device of the embodiment, it is possible to maximize the light reception intensity at the photodetector by using simple constitutions and ways.

In one embodiment of the present invention, the movement of the hologram element in the one direction on the plane perpendicular to the optical axis of the light-emitting element is conducted by moving the hologram element in a direction perpendicular to a boundary between the two light-receiving regions.

According to the manufacturing method of a pickup device of the one embodiment, the distance of shift of the hologram element in the one direction can be minimized, allowing the pickup device to be reduced in size.

In one embodiment of the present invention, the hologram element is turned around the optical axis of the light-emitting element after moving the hologram element in one direction on a plane perpendicular to the optical axis of the light-emitting element.

According to the manufacturing method of a pickup device of the present invention, again, the hologram element is turned around the optical axis of the light-emitting element and moved in one direction on the plane perpendicular to the optical axis of the light-emitting element so that the light reception intensity of the reflected light at the photodetector is maximized. Therefore, it is possible to reduce the displacement of the turning angle of the hologram element around the optical axis of the light-emitting element with respect to the package, and to prevent the pickup device from protruding from the housing when attached to the housing.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a perspective view showing a partly removed pickup device according to one embodiment of the present invention;

FIG. 2 is an explanatory view for explaining diffraction from a hologram element to a photodetector;

FIG. 3 is an explanatory view for explaining tuning of reflected light from the hologram element;

FIG. 4 is a perspective view showing a partly removed conventional pickup device;

FIG. 5 is an explanatory view for explaining tuning of diffracted light from the conventional hologram element;

FIG. 6 is an explanatory view for explaining the relation between a track on the information recording surface of a disk and three beams;

FIG. 7 is an explanatory view for explaining protrusion from a housing in the conventional pickup device; and

FIG. 8 is a simplified schematic view of a pickup device.

### DETAILED DESCRIPTION OF THE INVENTION

The present invention will be described in detail below by the embodiments shown in the drawings.

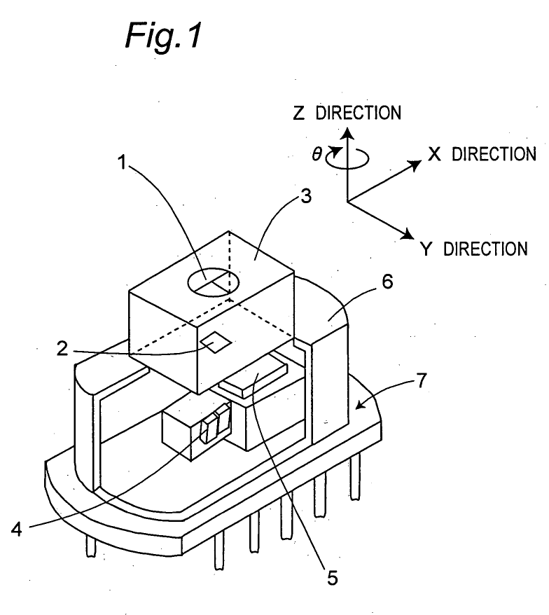

FIG. 1 is a perspective view showing a partly removed pickup device according to one embodiment of the present invention. The pickup device has a package 7 and an optical element 3 attached to a cap part 6 of the package 7. The optical element 3 is a glass block. A hologram element 1 is formed on the upper surface of the optical element 3, and a diffraction grating 2 is formed on the lower surface (surface facing the cap part 6 of the package 7) of the optical element 3.

A light-emitting element 4 (e.g., light emitting diode) and a photodetector 5 (e.g., photodiode) are attached to the inside of the package 7. The cap part 6 is constructed so that light is emitted from the light-emitting element 4 to the outside and light is made incident on the photodetector 5 from the outside, and for example, a hole is provided at the cap part 6.

The hologram element 1 emits incident light from one direction without change. The hologram element 1 emits incident light from the other direction opposite to the one direction toward another direction different from the one direction. The diffraction grating 2 splits the light from the light-emitting element 4 into three beams (tracking beams).

The light from the light-emitting element 4 is made incident on the diffraction grating 2, split into the three beams, made to pass through the hologram element 1, transformed into parallel light by a collimating lens (not shown), condensed by an object lens (not shown) and applied to the reflection surface of a disk.

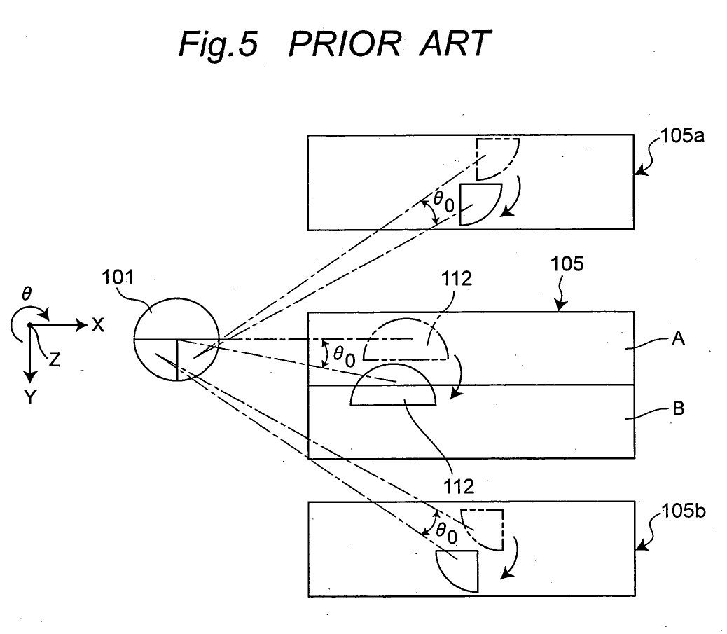

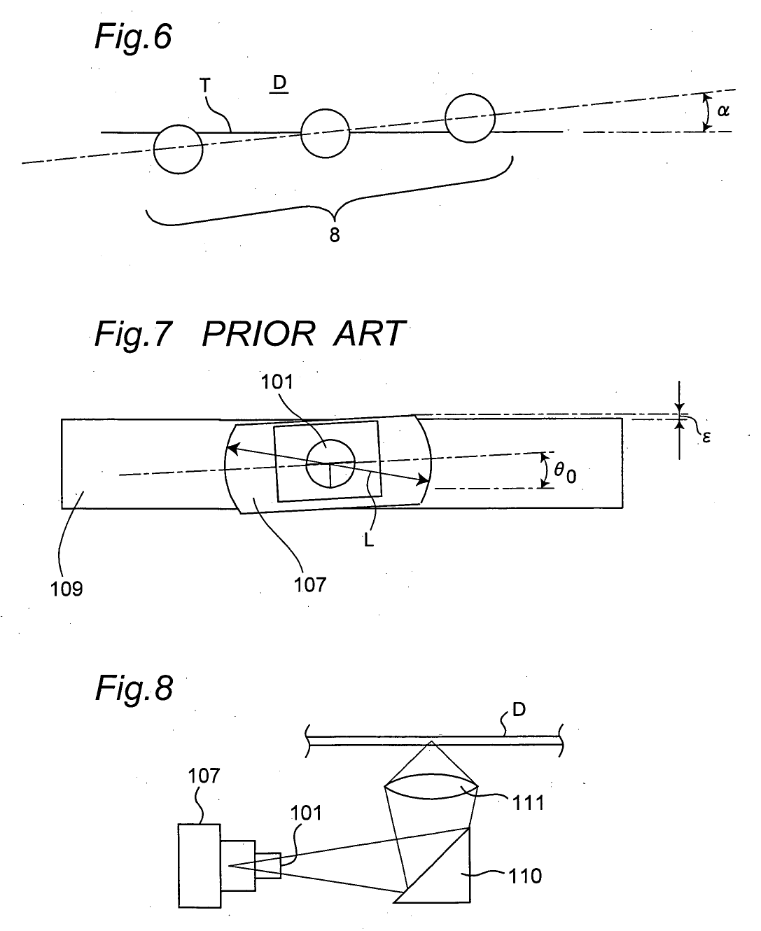

For example, as shown in FIG. 6, a plurality of pits (not shown) are formed in a line on the reflection surface of a disk D along a track T. When the applied light impinges on a portion other than the pits, the reflected light is almost wholly incident on the object lens. When the applied light impinges on any of the pits, the light is scattered (diffracted), and the reflected light is scarcely incident on the object lens. Thus, the presence or absence of the pits is discriminated, and the data recorded with the pits are read. The data read is executed by the zeroth order light that has passed through the diffraction grating 2. Therefore, it is necessary to prevent the zeroth order light from deviating from the track T. To achieve this, when the zeroth order light is located at the center of the track T, the positive and negative first order light are displaced symmetrically on both sides of the track T so as to equalize the outputs of the photodetector 5 which receives the reflected light from the disk D. When the zeroth order light deviates from the center of the track T, one of the positive and negative first order light applied to the pit is reduced in the ratio, and the other is increased. Then, the outputs of the photodetector 5 become asymmetrical. Therefore, when the outputs are so controlled as to become symmetrical, the zeroth order light does not deviate from the center of the track T.

The reflected light incident on the object lens passes through the collimating lens and is made incident on the photodetector 5 through the hologram element 1. The photodetector 5 has a plurality of light-receiving regions on which three beams are made incident, respectively. In addition, the reflected light from the hologram element 1 is also made incident on the light-receiving regions.

A manufacturing method of the pickup device is described next.

First, the light-emitting element 4 and the photodetector 5 are attached to the inside of the package 7, as shown in FIG. 1, and the optical element 3, to which the hologram element 1 and the diffraction grating 2 have been attached, is placed on the cap part 6 of the package 7.

Then, tuning is performed in the X and Y directions in such a manner that the prescribed outputs are produced from the three photodetectors 5 (this is called a rough tuning process) after reflecting light from the light-emitting element 4 on the disk via the diffraction grating 2 and the hologram element 1 and diffracting the reflected light through the hologram element 1 (as described in connection with the background art).

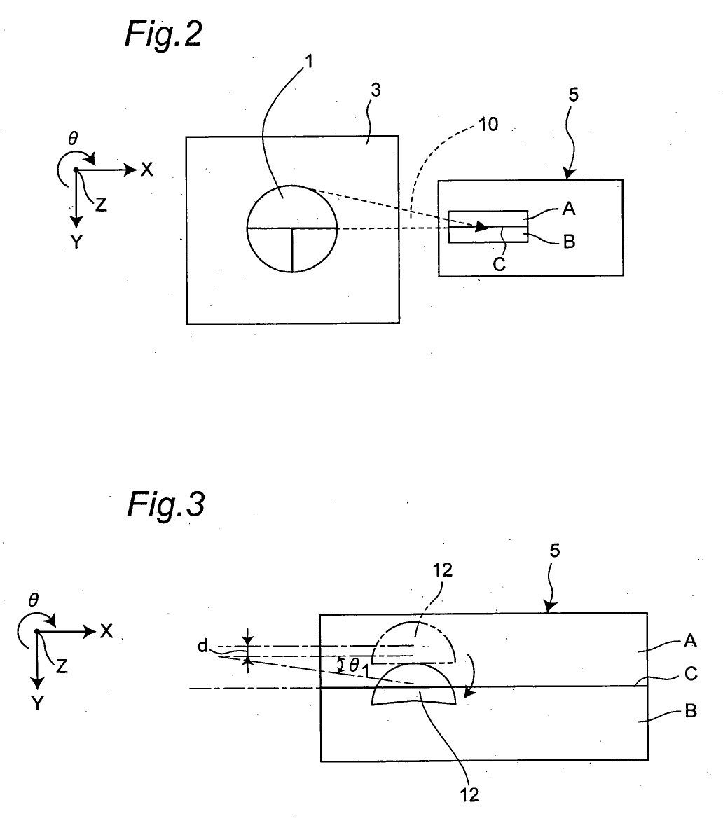

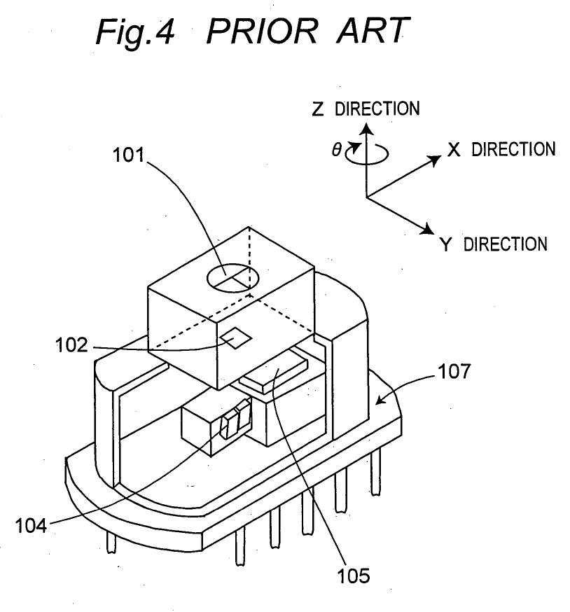

At this time, as shown in FIG. 2, the reflected light, which has returned from the disk, is guided to the photodetector 5 by the hologram element 1 just like diffracted light 10. The photodetector 5 has two light-receiving regions A and B on which the reflected light is made incident. The reflected light is converted into electrical signals equivalent to the quantities of light from the two light-receiving regions A and B. In the rough tuning process, tuning is performed so that a sum total of the outputs of the two light-receiving regions A and B come to have a prescribed value. The purpose of the subsequent fine tuning process is to make the outputs of the two light-receiving regions A and B become equal to each other. FIG. 2 shows only one photodetector 5, but the other two photodetectors are constructed as shown in, for example, FIG. 5.

Then, while the electrical signals are observed, the position of the hologram element 1 is moved in such a way that the electrical signals of the two light-receiving regions A and B become equalized. Thus, the light reception intensity at the photodetector 5 is maximized by making the reflected light evenly incident on the two light-receiving regions A and B.

In this case, the direction of the optical axis of the light-emitting element 5 is served as the Z axis in the figures. In a plane perpendicular to the optical axis (i.e. Z axis) of the light-emitting element 4, a direction in which a boundary C between the two light-receiving regions A and B extend is assumed to be the X axis, and a direction perpendicular to the boundary C is assumed to be the Y axis. The angular displacement of a turn around the optical axis (Z axis) of the light-emitting element 4 is assumed to be 0.

Specifically, as shown in FIG. 3, the hologram element 1 is moved by a distance d in the Y-axis direction (this is called Y-axis tuning) together with the optical element 3 (and the diffraction grating 2), and thereafter turned by an angle θ₁ around the Z axis (this is called rotary tuning), making the reflected light 12 evenly incident on the two light-receiving regions A and B. The amount of movement in the Y-axis direction should desirably be such an amount that the amount of tuning of the angle 0θbecomes minimized within a range in which the quantities of light of the three photodetectors 5 do not change.

Subsequently, the optical element 3 is fixed to the package 7 with an ultraviolet curing resin or the like to manufacture the pickup device.

Since the hologram element 1 is subjected to not only the rotary tuning but also the Y-axis tuning in the pickup device manufactured as described above, it is possible to reduce the amount of rotational shift (angular displacement) around the Z axis of the hologram element 1 with respect to the package 7.

As a result, it is not necessary to correct the pickup device by largely rotational shifting of the pickup device with respect to the housing when the pickup device is attached to the housing (housing 109 of FIG. 7) assembled with various optical components (collimating lens, object lens and so on). Thus, the package 7 of the pickup device can be almost prevented from protruding from the housing. Accordingly, the arrangement of the optical components satisfactorily improves in accuracy, allowing the pickup device to be reduced in size.

When the pickup device is attached to the housing, it is necessary to attach the pickup device in such a manner that the plurality of (three) beams 8 emitted from the pickup device at a definite angle (α) with respect to the track T of the disk D as shown in FIG. 6.

More in detail, in the pickup device manufactured by the manufacturing method of the present invention, as shown in FIGS. 3 and 6, the amount of correction of the angle of the pickup device with respect to the housing becomes (θ₁+α). This amount of correction (0₁+α) is smaller than the amount of correction (0₀+α) of the prior art shown in FIG. 7, and therefore, the protrusion amount ε of FIG. 7 is made approximately zero. In other words, the angle α can be tuned in a larger range if the tuning range of θ is the same, and therefore, it is possible to widen the range in which the angle of arrangement of the three beams 8 with respect to the direction of the track.

Specifically, the Y-axis tuning tolerates only about one to two micrometers, which corresponds to 0.06° to 0.12° in terms of the angular displacement (turning angle) and corresponds to about 10 to 20 micrometers in terms of the protrusion amount ε when the maximum outside dimension L of the package 107 is 9 mm.

The present invention is not limited to the above-stated embodiment. For example, the photodetector 5 may have three or more light-receiving regions. Also, the hologram element 1 may split the reflected light reflected on the disk into only two or four or more segments of light instead of three segments. Then, it is acceptable to split the reflected light into two or more beams of light and make the beams incident on the photodetector 5. Moreover, the hologram element 1 may be turned around the optical axis of the light-emitting element 4 and thereafter moved in one direction on the plane perpendicular to the optical axis of the light-emitting element 4.

The invention being thus described, it will be obvious that the invention may be varied in many ways. Such variations are not be regarded as a departure from the spirit and scope of the invention, and all such modifications as would be obvious to one skilled in the art are intended to be included within the scope of the following claims.

What is claimed is:

1. A manufacturing method of a pickup device, comprising the steps of:
attaching a light-emitting element and a photodetector to a package;
placing a hologram element on the package;
reflecting light applied from the light-emitting element to a disk via the hologram element and making the reflected light incident on the photodetector via the hologram element;
turning the hologram element around an optical axis of the light-emitting element and moving the hologram element in one direction on a plane perpendicular to the optical axis of the light-emitting element so that a light reception intensity of the reflected light at the photodetector is maximized; and
positioning the hologram element on the package.

2. The manufacturing method of a pickup device as claimed in claim 1, wherein
the photodetector has two light-receiving regions on which the reflected light is incident, and
the light reception intensity at the photodetector is maximized by making the reflected light evenly incident on the two light-receiving regions.

3. The manufacturing method of a pickup device as claimed in claim 2, wherein
The movement of the hologram element in the one direction on the plane perpendicular to the optical axis of the light-emitting element is conducted by moving the hologram element in a direction perpendicular to a boundary between the two light-receiving regions.
